(19) United States
(12) Patent Application Publication
(10) Pub. No.: US 2026/0123048 A1
(43) Pub. Date: Apr. 30, 2026

(54) METHOD FOR MANUFACTURING COMBINED FD-SOI PFET AND NFET TRANSISTORS

(71) Applicant: COMMISSARIAT À L'ENERGIE ATOMIQUE ET AUX ENERGIES ALTERNATIVES, PARIS (FR)

(72) Inventors: Nguyet-Phuong TRAN, GRENOBLE (FR); Philippe RODRIGUEZ, GRENOBLE (FR); Frédéric MILESI, GRENOBLE (FR); Laurent BRUNET, GRENOBLE (FR)

(21) Appl. No.: 19/373,537

(22) Filed: Oct. 29, 2025

(30) Foreign Application Priority Data
Oct. 30, 2024 (FR) 2411889

(51) Int. Cl. H10D 86/01; H10D 86/00

(52) U.S. Cl. CPC H10D 86/01; H10D 86/201

(57) ABSTRACT

A method for manufacturing semiconductor devices integrating PMOS and NMOS transistors is provided. The method begins by depositing a layer of silicon-germanium alloy SiGe onto a semiconductor-on-insulator substrate including a silicon layer on a buried oxide layer, which itself is located on a semiconductor support. An isolation trench is then created, separating the regions intended for the NMOS and PMOS transistors. The PMOS region is masked to allow a strain to be applied in the silicon layer of the NMOS region, via a STRASS recrystallization technique. Then, the NMOS region is masked and the mask of the PMOS region is removed in order to apply a strain by germanium enrichment.

### CROSS-REFERENCE TO RELATED APPLICATION

This application claims priority to foreign French patent application No. FR 2411889, filed on Oct. 30, 2024, the disclosure of which is incorporated by reference in its entirety.

### FIELD OF APPLICATION

The invention relates to a method for manufacturing a semiconductor structure comprising an N-type field effect transistor (NFET) having a tensile-strained silicon channel region, and a p-type field effect transistor (PFET) having a compression-strained silicon-germanium Si₍₁₋ₓ₎Geₓ channel region. More specifically, the semiconductive structure is produced on a substrate comprising a buried insulating layer.

### BACKGROUND

An example of MOSFET transistor technology with a buried insulator layer in the substrate is FD-SOI (Fully Depleted Silicon-on-Insulator) technology. This technology offers several advantages over technologies based on standard bulk substrates in terms of similar performance, power consumption and robustness. In general, in an FD-SOI type transistor the assembly formed by the source, the drain and the channel region is separated from the rest of the semiconductor substrate by a layer of insulating dielectric, generally oxide, referred to as BOX (Buried Oxide). The channel region is the zone located between the drain and the source in which the charge carrier conduction channel is formed when the transistor is in the on state. The conduction channel region is made of a semiconductor material.

When the channel region is made of a crystalline material, said region is arranged in a crystal lattice formed by periodic lattices. It is possible to manufacture layers of semiconductor materials with crystal lattices experiencing internal mechanical strains. The internal mechanical strains can be tensile or compression strains. On the scale of the crystal lattice, the internal mechanical strains experienced by the crystal lattices of the deposited layer cause asymmetries in said lattices and changes in the electromagnetic forces between atoms.

Engineering the internal strains of lattices in the layer forming the channel region allows the mobility of charge carriers to be increased, thereby providing at least the following advantages for the operation of the transistor:
increased switching speed: higher mobility of the charge carriers (electrons and holes) allows the transistors to switch more quickly between the “ON” and “OFF” states;
increased conduction current: improved mobility means that for the same applied voltage, the current flowing through the transistor channel is higher;
reduced energy consumption: by increasing carrier mobility, the transistors can operate efficiently at lower voltages, thereby reducing energy consumption and heat dissipation losses.

More specifically, for an NMOS transistor, an internal tensile strain applied to the lattices of the layer forming the channel zone improves electron mobility. For a PMOS transistor, an internal compression strain applied to the lattices of the layer forming the channel zone improves hole mobility.

However, in the solutions of the prior art, manufacturing NMOS transistors with a tensile-strained channel region and PMOS transistors with a compression-strained channel region requires two separate methods. This introduces additional steps to the overall manufacturing method of a semiconductor device comprising both types of the aforementioned transistors, resulting in longer manufacturing times and increasing the risks of technological variability within the same circuit.

More specifically, introducing a tensile strain into a silicon channel region can be achieved using the technique of “Strained Si by Top Recrystallization of Amorphized Si₍₁₋ₓ₎Geₓ on SOI”, known as STRASS, and the induction of a compression strain in a silicon-germanium alloy channel region can be achieved using the “silicon enrichment with germanium” technique. Executing these two operations involves the epitaxial growth of two separate layers of silicon-germanium Si₍₁₋ₓ₎Geₓ. Both layers have visible lateral faces of the epitaxial layers of Si₍₁₋ₓ₎Geₓ. The lateral faces of the layer of Si₍₁₋ₓ₎Geₓ obtained by epitaxy present increased risks of dislocations occurring during the amorphization operations required for creating internal strains according to the methods of the prior art. Dislocations reduce the mechanical robustness of the manufactured semiconductor device.

In addition, the appearance of dislocations in the layers of Si₍₁₋ₓ₎Geₓ can induce short circuits in the manufactured semiconductor device. Indeed, manufacturing NMOS/PMOS transistors generally requires a silicidation step. This is a step of forming silicides, which are metal compounds obtained by a reaction between silicon and a metal, such as titanium, cobalt or nickel. The main aim is to reduce the contact resistance between, on the one hand, the source and the drain of each transistor and, on the other hand, the metal contact layers. In the event of dislocations, silicidation can induce electrically conductive zones in the dislocations, which can cause short circuits and therefore a malfunction in the device.

### Response to the Problem and Solution Provided

In order to overcome the limitations of the existing solutions, the invention proposes a manufacturing method that combines the manufacture of NMOS transistors with a tensile-strained channel zone and the manufacture of PMOS transistors with a compression-strained channel zone. The method according to the invention allows both types of transistors to be produced from a single layer of Si₍₁₋ₓ₎Geₓ before the step of separating the two zones by STI, which does not exhibit any apparent lateral faces when applying thermal annealing. This reduces the risks of dislocations occurring and thus improves the mechanical robustness and the electrical reliability of the manufactured device.

In addition, the method according to the invention allows the number of steps to be reduced compared with the methods of the prior art, thereby reducing the manufacturing time and the energy consumption of the method for manufacturing PMOS and NMOS transistors with strained semiconductor channel zones.

Furthermore, the method according to the invention allows the crystalline properties and therefore the electrical properties of the PMOS and NMOS channel zones to be better controlled by controlling the following two parameters: the thickness of the common layer of Si₍₁₋ₓ₎Geₓ epitaxially deposited during the manufacturing method according to the invention, and the percentage of germanium in said layer.

A semiconductive structure with increased charge carrier mobility in PMOS and NMOS transistors is obtained by virtue of the method according to the invention, without degrading the mechanical or electrical robustness of said device.

### SUMMARY OF THE INVENTION

The aim of the invention is a method for manufacturing a semiconductor device comprising at least one PMOS transistor and at least one NMOS transistor, said method comprising the following steps of:
(a) depositing a layer of Si₍₁₋ₓ₎Geₓ alloy, with 0<x<1, onto a semiconductor-oninsulator substrate, said substrate comprising a silicon layer disposed on a buried oxide layer that is disposed on a bulk support made of a semiconductor material
(b) manufacturing an isolation trench extending from the layer of Si₍₁₋ₓ₎Geₓ to at least the buried oxide layer, the dielectric isolation trench separating a first region dedicated to said NMOS transistor and a second region dedicated to said PMOS transistor
(c) masking the portion of the layer of Si₍₁₋ₓ₎Geₓ located in the second region by depositing a first masking structure
(d) inducing a strain in the crystal lattice of the silicon layer located in the first region using a top recrystallization method on the previously amorphized layer of Si₍₁₋ₓ₎Geₓ
(e) masking the portion of the silicon layer located in the first region by depositing a second masking structure and etching the first masking structure
(f) inducing a strain in the crystal lattice of the silicon layer located in the second region using a germanium enrichment method.

According to a particular aspect of the invention, the first masking structure is made of dielectric material. According to a particular aspect of the invention, the second masking structure is made of dielectric material.

According to a particular aspect of the invention, the manufacturing method further comprises the following step of: (g) manufacturing the drain and the source of the NMOS transistor in the silicon layer located in the first region, and manufacturing the drain and the source of the PMOS transistor in the portion of the germanium-enriched silicon layer located in the second region.

According to a particular aspect of the invention, the manufacturing method further comprises a step of thinning by etching the portion of the layer of Si₍₁₋ₓ₎Geₓ located in the second region before step (f).

According to a particular aspect of the invention, step (d) comprises the following sub-steps of:
(d1) ion implantation into the stack formed by the semiconductive layer and the layer of Si₍₁₋ₓ₎Geₓ in the first region so as to render the silicon layer amorphous and render the layer of Si₍₁₋ₓ₎Geₓ in the first region partially amorphous
(d2) thermal annealing of the structure so as to recrystallize the semiconductive layer and the layer of Si₍₁₋ₓ₎Geₓ in the first region;
(d3) removing the recrystallized layer of Si₍₁₋ₓ₎Geₓ in the first region by etching.

According to a particular aspect of the invention, the thermal annealing step (d2) is carried out at a temperature below 850° C.

According to a particular aspect of the invention, the ion implantation step (d1) is carried out with ions comprising silicon or germanium or argon or fluorine, or carbon, or nitrogen or oxygen.

According to a particular aspect of the invention, step (f) comprises the following sub-steps of:
(f1) thermal oxidation of the layer of Si₍₁₋ₓ₎Geₓ located in the second region so as to diffuse any germanium atoms toward the silicon layer in the second region and convert the layer of Si₍₁₋ₓ₎Geₓ into a layer of SiO₂;
(f2) thermal annealing of the structure so as to recrystallize the germanium-enriched silicon layer in the second region;
(f3) removing the layer of SiO₂ formed in the second region by etching.

According to a particular aspect of the invention, the thermal oxidation step (f1) is carried out at a temperature ranging between 700° C. and 1,100° C.

According to a particular aspect of the invention, the thermal annealing step (f2) is carried out at a temperature ranging between 700° C. and 1,100° C.

According to a particular aspect of the invention, the deposition carried out during step (a) involves epitaxial growth of a crystalline layer of an alloy of Si₍₁₋ₓ₎Geₓ.

According to a particular aspect of the invention, the layer of Si₍₁₋ₓ₎Geₓ deposited during step (a) is an amorphous layer. The manufacturing method further comprises a step of crystallizing said amorphous layer of Si₍₁₋ₓ₎Geₓ implemented before step (d) for converting the amorphous layer of Si₍₁₋ₓ₎Geₓ into a crystalline layer.

According to a particular aspect of the invention, the layer of Si₍₁₋ₓ₎Geₓ is formed during step (a) with a thickness ranging between 6 nm and 25 nm.

According to a particular aspect of the invention, the layer of Si₍₁₋ₓ₎Geₓ formed during step (a) comprises 10% to 50% germanium, and preferably 20% to 30% germanium.

According to a particular aspect of the invention, the thickness of the layer of Si₍₁₋ₓ₎Geₓ deposited during step (a) is equal to 8 nm.

According to a particular aspect of the invention, at least one from among the first masking structure or the second masking structure comprises a layer of SiN disposed on a layer of SiO₂.

The invention also relates to a semiconductor device comprising a PMOS transistor and an NMOS transistor separated from each other by a dielectric isolation trench. The NMOS transistor is produced in a crystalline silicon layer disposed on a buried oxide layer. The lattices of the crystalline silicon layer experience internal mechanical tensile strains. The PMOS transistor is produced in a crystalline layer of Si₍₁₋ₓ₎Geₓ disposed on a buried oxide layer. The lattices of the crystalline layer of Si₍₁₋ₓ₎Geₓ experience internal mechanical compression strains.

According to a particular aspect of the invention, the amplitude of the mechanical tensile strains is greater than or equal to 1 GPa.

### BRIEF DESCRIPTION OF THE DRAWINGS

Further features and advantages of the present invention will become apparent upon reading the following description with reference to the accompanying drawings.

FIG. 1 illustrates the flowchart of a manufacturing method according to a first embodiment of the invention.

FIG. 2a illustrates the structure obtained on completion of the first step of the manufacturing method according to the first embodiment of the invention.

FIG. 2b illustrates the structure obtained on completion of the second step of the manufacturing method according to the first embodiment of the invention.

FIG. 2c illustrates the structure obtained on completion of the third step of the manufacturing method according to the first embodiment of the invention.

FIG. 2d illustrates the structure obtained on completion of the fourth step of the manufacturing method according to the first embodiment of the invention.

FIG. 2e illustrates the structure obtained on completion of the fifth step of the manufacturing method according to the first embodiment of the invention.

FIG. 2f illustrates the structure obtained on completion of the sixth step of the manufacturing method according to the first embodiment of the invention.

FIG. 2g illustrates the structure obtained on completion of the seventh step of the manufacturing method according to the first embodiment of the invention.

FIG. 3 illustrates the sub-steps of the “top recrystallization of amorphized Si₍₁₋ₓ₎Geₓ on SOI” (STRASS) technique.

FIG. 4 illustrates the sub-steps of silicon enrichment with germanium.

FIG. 5 illustrates a semiconductor device according to the invention.

FIG. 6 illustrates the flowchart of a manufacturing method according to a second embodiment of the invention.

FIG. 7a illustrates the structure obtained on completion of the first step of the manufacturing method according to the second embodiment of the invention.

FIG. 7b illustrates the structure obtained on completion of the second step of the manufacturing method according to the second embodiment of the invention.

FIG. 7c illustrates the structure obtained on completion of the third step of the manufacturing method according to the second embodiment of the invention.

FIG. 7d illustrates the structure obtained on completion of the fourth step of the manufacturing method according to the second embodiment of the invention.

FIG. 7e illustrates the structure obtained on completion of the fifth step of the manufacturing method according to the second embodiment of the invention.

FIG. 7f illustrates the structure obtained on completion of the sixth step of the manufacturing method according to the second embodiment of the invention.

FIG. 7g illustrates the structure obtained on completion of the seventh step of the manufacturing method according to the second embodiment of the invention.

### DETAILED DESCRIPTION

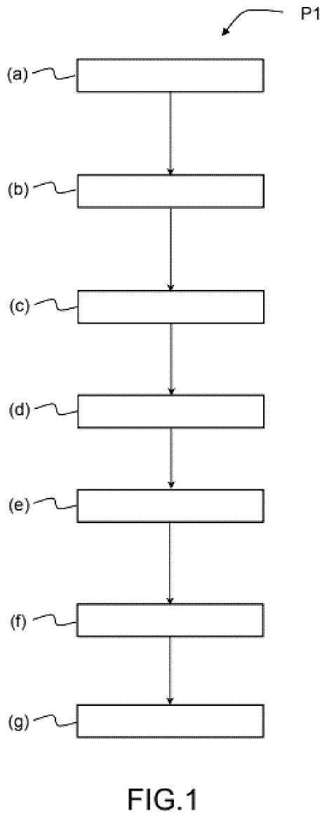

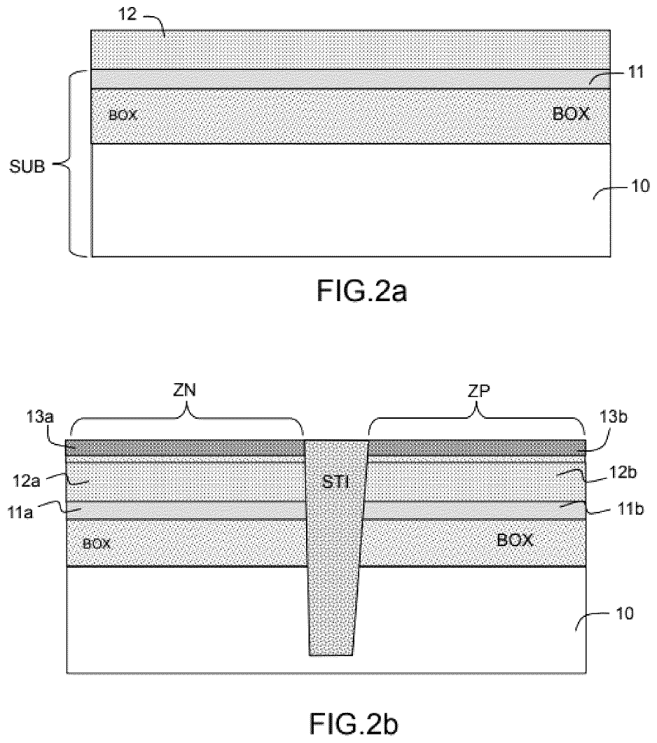

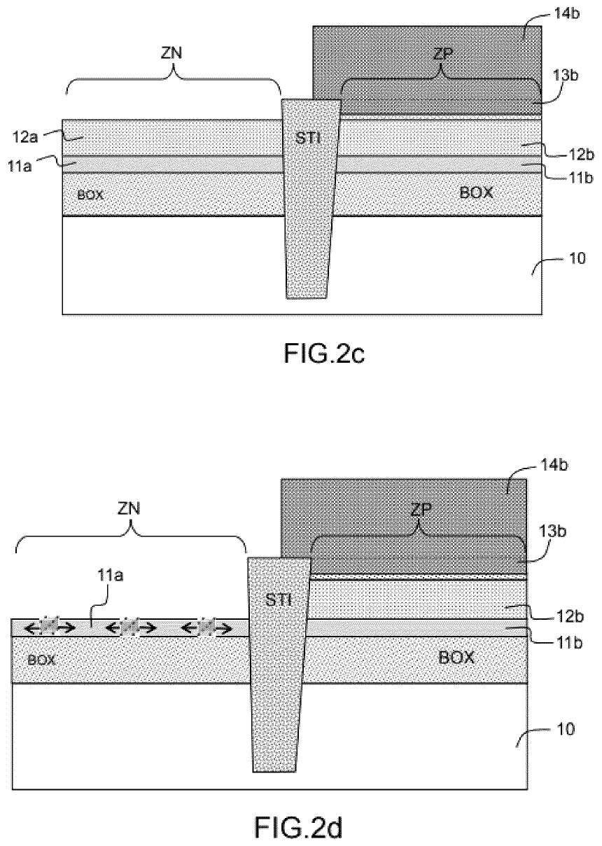

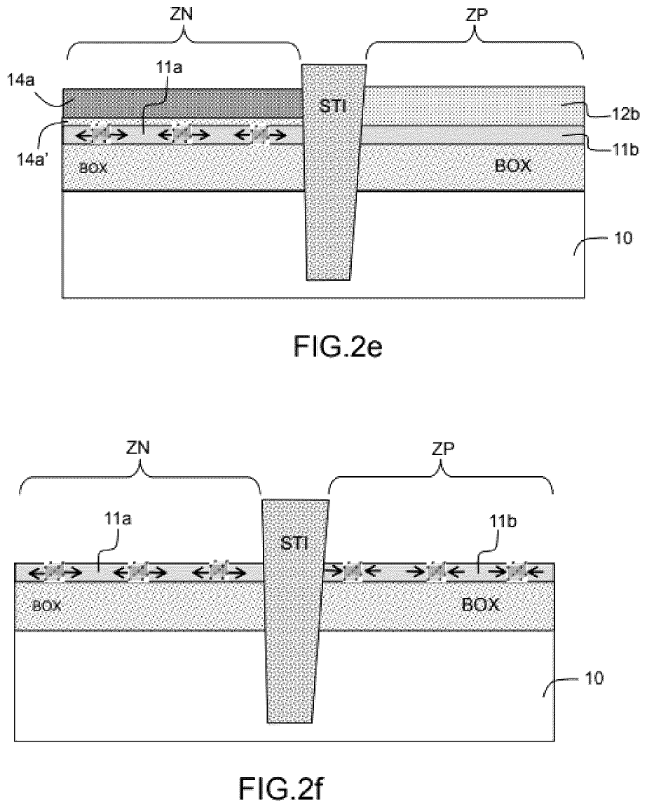

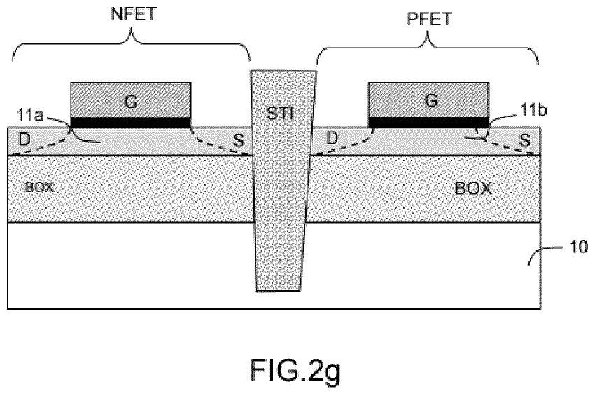

FIG. 1 illustrates the flowchart of the method P1 for manufacturing a photonic device D1 according to a first embodiment of the invention. FIGS. 2a to 2g illustrate the steps of the method P1 according to the invention.

The first step (a) involves depositing a crystalline layer 12 of an Si₍₁₋ₓ₎Geₓ alloy onto a semiconductor-on-insulator (SOI) type substrate SUB by epitaxy. The intermediate structure obtained on completion of the first step (a) is illustrated in FIG. 2a. The substrate SUB comprises a silicon layer 11 disposed on a buried oxide layer BOX that is disposed on a bulk support made of a semiconductor material 10. The crystalline layer 12 of Si₍₁₋ₓ₎Geₓ is disposed on the silicon layer 11 of the substrate SUB. The thickness of the silicon layer 11 ranges between 5 and 10 nm. The crystalline layer 12 of Si₍₁₋ₓ₎Geₓ is produced by epitaxy from the silicon layer 11; this is referred to as heteroepitaxy. During this process, the silicon layer 11 on which the layer of Si₍₁₋ₓ₎Geₓ grows imposes a crystalline orientation on the latter. The epitaxial silicon-germanium alloy assumes the lattice parameter of the layer 11 in the growth plane. The thickness of the layer 12 ranges between 6 nm and 25 nm. Byway of an example, the epitaxy of the silicon and germanium alloy layer is achieved by vapor phase epitaxy. The stoichiometry of the epitaxial layer 12 is controlled so as to obtain a layer 12 of Si₍₁₋ₓ₎Geₓ comprising 25% to 30% germanium.

The second step (b) involves manufacturing an isolation trench (STI) extending from the epitaxial layer 12 to the bulk semiconductor substrate 10. The intermediate structure obtained on completion of the second step (b) is illustrated in FIG. 2b. The dielectric isolation trench (STI) delimits two spatial regions: a first region ZN and a second region ZP. The first region ZN is intended to accommodate an NMOS transistor. The second region ZP is intended to accommodate a PMOS transistor. The second step (b) comprises the following sub-steps: the first sub-step (b1) involves depositing a protective structure over the entire surface of the layer 12 of Si₍₁₋ₓ₎Geₓ, comprising a first protective layer of SiO₂ and a second protective layer of silicon nitride Si₃N₄. The second sub-step (b2) involves manufacturing a bulk semiconductor substrate 10 using lithography and etching operations. The third sub-step (b3) involves filling the trench with an insulating material, typically silicon oxide SiO₂. This is achieved by chemical vapor deposition (CVD). The insulating material is filled by depositing TEOS (Si(OC₂H₅)₄) used as a precursor in chemical vapor deposition methods in order to form the silicon oxide filling. The TEOS is deposited at a low temperature below 650° C., for example, at 540° C. Low-temperature deposition prevents germanium from migrating from the layer 12 to the silicon layer 11. The fourth sub-step (b4) involves planarizing the upper surface of the wafer by mechanical-chemical polishing. The protective structure is thus split into two distinct portions: a first portion 13a located in the first region ZN and a second portion 13b located in the second region ZP. The layer 12 of Si₍₁₋ₓ₎Geₓ is split into two distinct portions: a first portion 12a located in the first region ZN and a second portion 12b located in the second region ZP. The layer 11 of Si is split into two distinct portions: a first portion 11a located in the first region ZN and a second portion 11b located in the second region ZP. The buried oxide layer BOX is split into two distinct portions separated by the STI trench.

The third step (c) involves masking the portion of the layer 12b of Si₍₁₋ₓ₎Geₓ located in the second region ZP by depositing a first dielectric masking structure and etching the portion 13a of the protective structure located in the first region ZN. The intermediate structure obtained on completion of the third step (c) is illustrated in FIG. 2c. The masking structure is, for example, made of a layer of silicon nitride Si₃N₄. The protective structure located in the first region ZN is removed by etching so as to expose the first portion 12a of the layer of Si₍₁₋ₓ₎Geₓ located in the first region ZN.

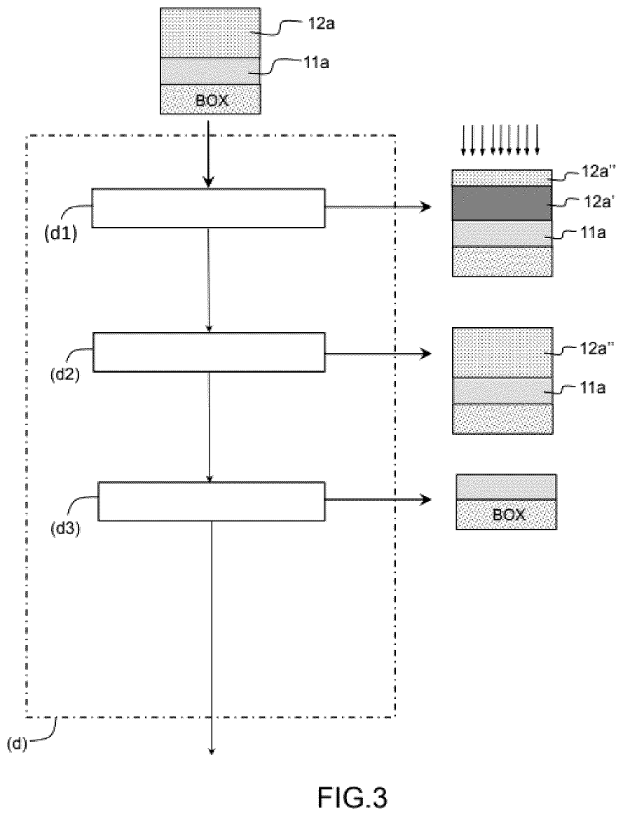

The fourth step (d) involves inducing a tensile strain in the crystal lattice of the portion of the layer 11a of Si located in the first region ZN using the “top recrystallization of amorphized Si₍₁₋ₓ₎Geₓ on SOI” (STRASS) technique. By way of a reminder, the layer 11a is intended to accommodate the channel region of the NMOS transistor being manufactured. Introducing a tensile strain into the crystal lattice of the layer 11a increases electron mobility in the future channel region of the NMOS transistor. The fourth step (d) comprises the following sub-steps illustrated in the flowchart of FIG. 3: the first sub-step (d1) involves carrying out ion implantation in the stack formed by the semiconductive layer 11a and the layer 12a of Si₍₁₋ₓ₎Geₓ of the first region ZN. The ions that are used include silicon or germanium or argon or fluorine, or carbon, or nitrogen or oxygen. The ion implantation dose ranges between 1e14 and 1e15 ions/cm². The ion implantation operation amorphizes the silicon layer 11a and partially amorphizes the layer 12a. The amorphous portion 12a′ of the layer 12a is confined between the amorphous layer 11a and an upper portion 12′ of the layer 12a′ that remains crystalline. The second sub-step (d2) involves thermally annealing the structure at a temperature that is less than or equal to 850° C. for a period that varies between 30 seconds and 30 minutes, preferably 5 to 15 minutes. This allows the semiconductive layer 11a and the layer 12a of Si₍₁₋ₓ₎Geₓ to recrystallize in the first region ZN without germanium diffusing from the layer 12a to the silicon layer 11a located in the same region ZN. During recrystallization, the annealing allows the atoms in the layers 11a and 12a to rearrange themselves into the crystal structure of the upper crystalline part 12a″, inducing a tensile strain in the silicon layer 11a as the crystal lattice adapts to that of the layer 12a″ made of silicon-germanium alloy during this operation. The third sub-step (d3) involves removing the layer 12a of Si₍₁₋ₓ₎Geₓ from the first region ZN by chemical etching, for example with hydrogen chloride HCl in an epitaxial growth tool, or by wet etching using, for example, TMAH or NH₄OH or peracetic acid. Alternatively, the third sub-step (d3) is carried out by dry gas etching using NF₃ or CIF₃. The intermediate structure obtained on completion of the fourth step (d) is illustrated in FIG. 2d. The layer 11a intended to accommodate the channel region of the NMOS transistor has a tensile-strained crystal lattice, which improves the mobility of the electrons in said layer 11a.

The fifth step (e) involves masking the strained silicon layer 11a located in the first region ZN by depositing a second dielectric masking structure and etching the first masking structure 14a, 14a′ in order to unmask the layer 12b of Si₍₁₋ₓ₎Geₓ. The intermediate structure obtained on completion of the fifth step (e) is illustrated in FIG. 2e. The masking structure 14a, 14a′ is produced, for example, by a stack formed by a layer 14a′ of SiO₂ and a layer 14a of silicon nitride Si₃N₄. The layer 14a′ of SiO₂ acts as a mechanical strain buffer to protect the surface of the layer 11a. Indeed, the SiO₂ layer 14a′ acts as a barrier layer when etching the SiN layer, and removing the thin SiO₂ layer results in a more homogeneous layer 12.

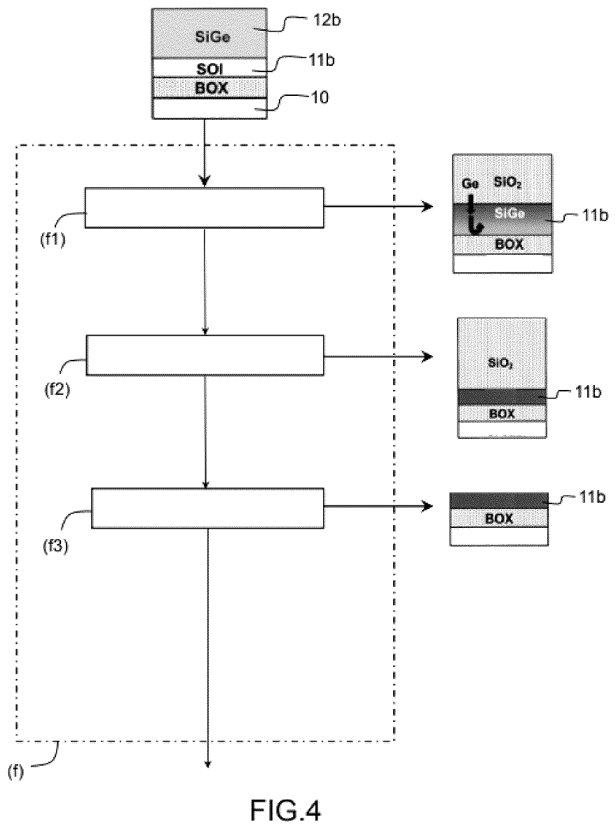

The sixth step (f) involves inducing a compression strain in the crystal lattice of the silicon layer 11b located in the second region ZP by “germanium enrichment”. It should be noted that the layer 11b is intended to accommodate the channel region of the PMOS transistor being manufactured. Introducing a compression strain into the crystal lattice of the layer 11b increases the mobility of holes in the future channel region of the PMOS transistor. The sixth step (f) comprises the following sub-steps illustrated in the flowchart of FIG. 4: the first sub-step (f1) involves thermal oxidation of the layer 12b of Si₍₁₋ₓ₎Geₓ. The thermal oxidation gradually converts the layer 12b of Si₍₁₋ₓ₎Geₓ into a layer of SiO₂, starting from the upper surface of the layer 12b toward the interface with the layer 11b of Si. Indeed, the layer 12b is exposed to an oxidizing environment, generally oxygen at high temperatures. Oxidation is carried out at a temperature ranging between 700° C. and 1,100° C., preferably between 850° C. and 1,050° C., in order to enrich the layer 11b of silicon with germanium. The silicon atoms in the layer 12b oxidize in order to form silicon dioxide SiO₂, while the germanium atoms do not oxidize as easily. The process pushes the germanium atoms toward the unoxidized region and toward the silicon layer 11b, enriching the layer 11b with germanium. This sub-step then allows the germanium atoms to diffuse toward the silicon layer 11b in the second region ZP and the layer 12b to be converted into a layer of SiO₂. For example, a silicon layer 11b enriched with a germanium content ranging between 10% and 80%, preferably between 10% and 50% or even between 20% and 40%, and more preferably between 20% and 30%, is obtained. The second sub-step (f2) involves thermally annealing the structure in order to homogenize the silicon layer 11b previously enriched with germanium in the second region ZP. The thermal annealing is carried out at a temperature ranging between 700° C. and 1,100° C., preferably between 850° C. and 1,050° C., for a period ranging between 30 minutes and 3 hours. To ensure sufficient and homogeneous diffusion of the germanium, the annealing time must be adapted to the temperature that is used in order to obtain a sufficient thermal budget: by way of an example, the sub-step (f2) is carried out at 900° C. for 3 hours, or at 1,050° C. for 30 minutes. This allows a strained crystal lattice to be obtained in the silicon layer 11b enriched with germanium that is completely homogeneous. The crystal lattices experience a compression strain, which increases the mobility of the holes. The temperature range selected for thermal annealing also at the same time allows the structure of the isolation trench (STI) to become more dense and solid. The third sub-step (f3) involves removing the oxidized layer 2b formed in the second region ZP by etching.

Advantageously, the method P1 comprises a step of thinning the layer 12b of Si₍₁₋ₓ₎Geₓ before carrying out the enrichment step (f). This optional step allows the degree of germanium enrichment of the layer 11b to be adjusted on completion of step (f). Indeed, the percentage of germanium that diffuses into the layer 11b depends on two initial parameters: the thickness of the layer 12b and the percentage of germanium in said layer 12b.

The intermediate structure obtained on completion of the sixth step (f) is illustrated in FIG. 2f. The layer 11b, which is intended to accommodate the channel region of the PMOS transistor, has a compression-strained crystal lattice, which improves the mobility of the holes in said layer 11a.

The seventh step (g) involves manufacturing the NMOS transistor in the strained layer 11a and manufacturing the PMOS transistor in the strained layer 11b. Both transistors are manufactured using standard CMOS manufacturing steps, including lithography, doping in order to form the drains D and the sources S, and deposition of the gates G. The intermediate structure obtained on completion of the seventh step (g) is illustrated in FIG. 2g.

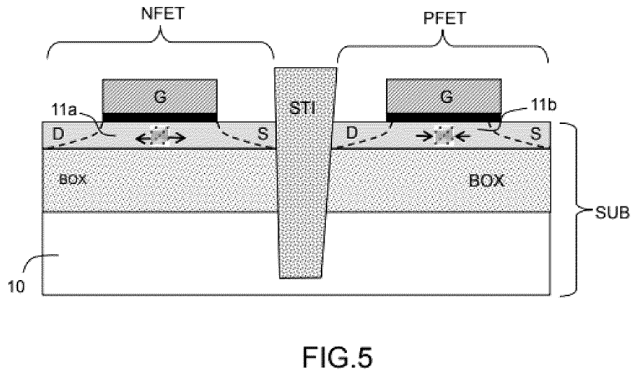

FIG. 5 illustrates a semiconductor device D1 according to the invention. The semiconductor device D1 is obtained by the method P1 according to the invention. The semiconductor device D1 comprises a PMOS transistor and an NMOS transistor separated from each other by a dielectric isolation trench (STI). The NMOS transistor comprises a gate G, a drain D and a source formed in a channel region formed by a layer 11a. The layer 11a is a crystalline silicon layer. The lattices of the layer 11a experience internal mechanical tensile strains. The layer 11a is disposed on a buried oxide layer BOX in a silicon substrate 10. The internal strains in the layer 11a allow the electron mobility in the channel region of the NMOS transistor to be increased. The PMOS transistor comprises a gate G, a drain D and a source S formed in a channel region formed by a layer 11b. The layer 11b is a crystalline silicon-germanium alloy layer. The lattices of the layer 11b experience internal mechanical compression strains. The layer 11b is disposed on a buried oxide layer BOX in the silicon substrate 10. The internal strains of the layer 11b allow the mobility of the holes in the channel region of the PMOS transistor to be increased.

According to an advantageous embodiment of the invention, the amplitude of the mechanical tensile strains in the layer 11a is greater than or equal to 1 GPa. According to an advantageous embodiment of the invention, the amplitude of the mechanical compression strains in the layer 11b ranges between 0.8 GPa and 1.6 GPa. These strain values allow better mobility of the charge carriers to be obtained in the context of an FD-SOI transistor. By way of a non-limiting example, for a germanium concentration of 25% in the layer 11b, a compression strain of 1.5 GPa is achieved. The method P1 according to the invention allows these strain amplitude values to be achieved with fewer steps compared with the methods of the prior art. By way of an example, a tensile strain of more than 1 GPa in the layer 11a and a compression strain of more than 1 GPa in the layer 11b can be obtained with a common layer 12 of Si₍₁₋ₓ₎Geₓ deposited in a single step by epitaxy (step (a)), with a thickness of 8 nm and a germanium concentration of 30%.

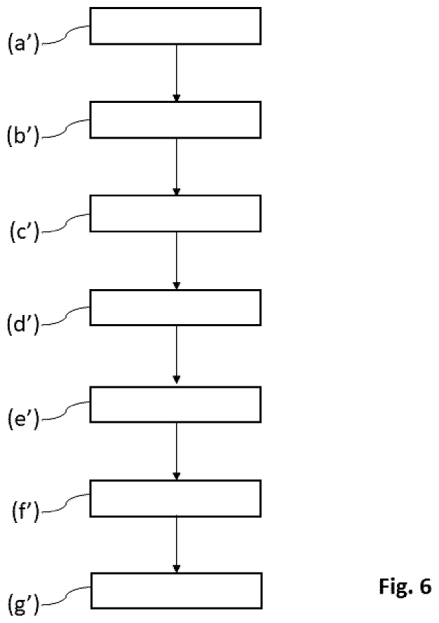

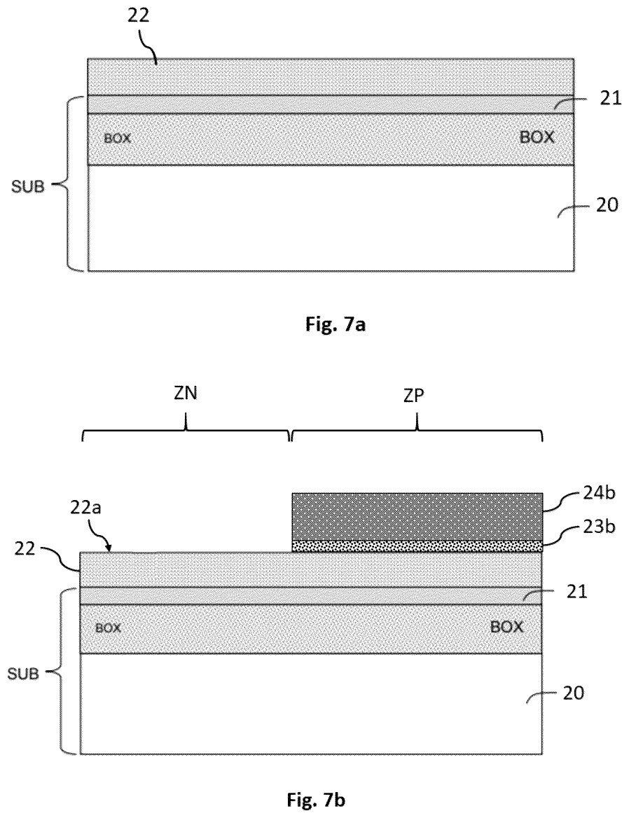

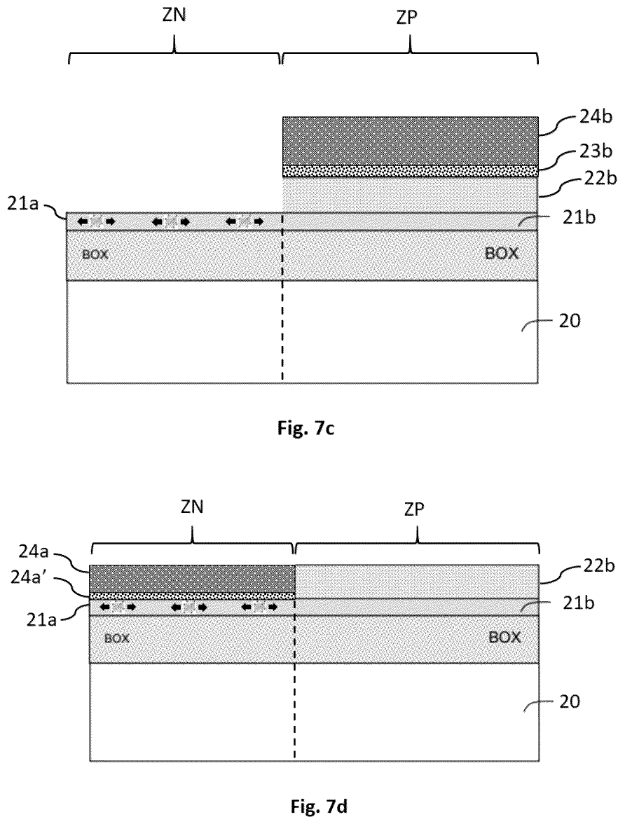

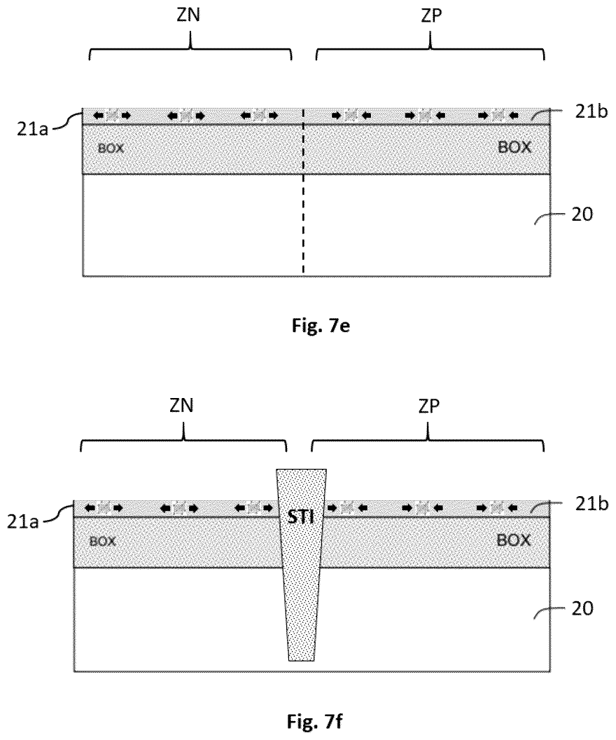

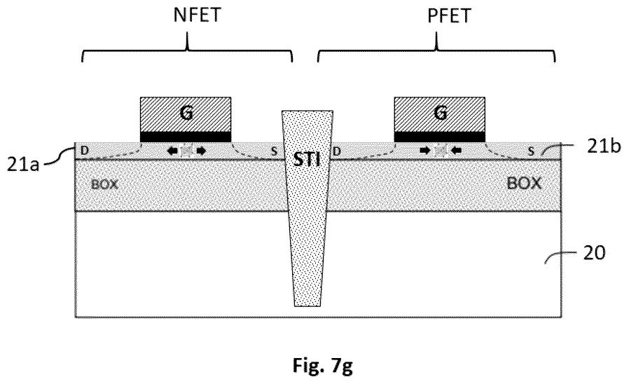

FIG. 6 illustrates the flowchart of the method P2 for manufacturing the photonic device D1 according to a second embodiment of the invention. FIGS. 7a to 7g illustrate the steps of the method P2 according to the invention.

According to the second embodiment of the invention, the isolation trench (STI) is produced at the end of the method. As in the first embodiment, the structure is split into a first region ZN and a second region ZP. The layer 22 of Si₍₁₋ₓ₎Geₓ is split into two distinct portions: a first portion 22a located in the first region ZN and a second portion 22b located in the second region ZP. The layer 21 of Si is split into two distinct portions: a first portion 21a located in the first region ZN and a second portion 21b located in the second region ZP. Advantageously, according to the second embodiment of the invention, STI is no longer consumed and the constraints relating to STI manufacturing are lower. For example, there are no temperature constraints with the second embodiment.

According to the second embodiment, the first step (a′) involves depositing a crystalline layer 22 of an Si₍₁₋ₓ₎Geₓ alloy onto a semiconductor-on-insulator (SOI) type substrate SUB by epitaxy. The substrate SUB comprises a silicon layer 21 disposed on a buried oxide layer BOX that is disposed on a bulk support made of a semiconductor material 20. The crystalline layer of Si₍₁₋ₓ₎Geₓ 22 is disposed on the silicon layer 21 of the substrate SUB. The thickness of the silicon layer 21 ranges between 5 and 10 nm, preferably 8 nm. The crystalline layer of Si₍₁₋ₓ₎Geₓ 22 is produced by epitaxy from the silicon layer 21. During this method, the silicon layer 21 on which the layer of Si₍₁₋ₓ₎Geₓ grows imposes a crystalline orientation on the latter. The epitaxial silicon-germanium alloy assumes the lattice parameter of the layer 21 in the growth plane. The thickness of the layer 22 ranges between 6 nm and 25 nm, preferably between 8 and 15 nm. By way of an example, the epitaxy of the silicon and germanium alloy layer is achieved by vapor phase epitaxy. The stoichiometry of the epitaxial layer 22 is controlled so as to obtain a layer 22 of Si₍₁₋ₓ₎Geₓ comprising 25% to 30% germanium, preferably 27%. The intermediate structure obtained on completion of the first step (a′) is illustrated in FIG. 7a.

The second step (b′) involves depositing a full-plate protective structure 23 and then selectively etching it. The protective structure 23 comprises two distinct portions: a first portion 23a, 23b located in the first region ZN and a second portion 23b, 24b located in the second region ZP. The portion 23a, 23b of the protective structure 23 located in the first region ZN is then etched. The masking structure is produced, for example, with a layer of silicon nitride Si₃N₄ and a layer of silicon oxide SiO₂. The portion 23a, 23b is removed by etching so as to expose the first portion 22a of the layer of Si₍₁₋ₓ₎Geₓ located in the first region ZN. The intermediate structure obtained on completion of the second step (b′) is illustrated in FIG. 7b.

The third step (c′) involves inducing a tensile strain in the crystal lattice of the portion of the layer 21a of Si located in the first region ZN using the “top recrystallization of amorphized Si₍₁₋ₓ₎Geₓ on SOI” (STRASS) technique. The third step (c′) comprises a first sub-step (c′1), a second sub-step (c′2) and a third sub-step (c′3). The first sub-step (c′1) involves carrying out ion implantation in the stack formed by the semiconductive layer 21a and the layer 22a of Si₍₁₋ₓ₎Geₓ of the first region ZN. The ions that are used include silicon or germanium or argon or fluorine, or carbon, or nitrogen or oxygen. The ion implantation dose ranges between 1e14 and 1e15 ions/cm². The second sub-step (c′2) involves thermally annealing the structure at a temperature that is less than or equal to 850° C. for a period that varies between 30 seconds and 10 minutes, preferably 5 minutes. The third sub-step (c′3) involves removing the layer 22a of Si₍₁₋ₓ₎Geₓ from the first region ZN by chemical etching, for example with hydrogen chloride HCl in an epitaxial growth tool, or by wet etching using, for example, TMAH or NH₄OH or peracetic acid. Alternatively, the third sub-step (c′3) is carried out by dry gas etching using NF₃ or CIF₃. The intermediate structure obtained on completion of the third step (c′) is illustrated in FIG. 7c.

The fourth step (d′) involves masking the strained silicon layer 21a located in the first region ZN by depositing a second dielectric masking structure 24a, 24a′ and etching the masking structure 23b, 24b of the second region ZP in order to unmask the layer 22b of Si₍₁₋ₓ₎Geₓ. The masking structure 24a, 24a′ is produced, for example, by a stack formed by a layer 24a′ of SiO₂ and a layer 24a of silicon nitride Si₃N₄. The layer 24a′ of SiO₂ acts as a mechanical strain buffer to protect the surface of the layer 21a. Indeed, the SiO₂ layer 24a′ acts as a barrier layer when etching the SiN layer, and removing the thin SiO₂ layer results in a more homogeneous layer 22. The intermediate structure obtained on completion of the fourth step (d′) is illustrated in FIG. 7d.

The fifth step (e′) involves inducing a compression strain in the crystal lattice of the silicon layer 21b located in the second region ZP by “germanium enrichment”. Introducing a compression strain into the crystal lattice of the layer 21b increases the mobility of holes in the future channel region of the PMOS transistor. The fifth step (e′) comprises a first sub-step (e′1), a second sub-step (e′2) and a third sub-step (e′3). The first sub-step (e′1) involves thermal oxidation of the layer 22b of Si₍₁₋ₓ₎Geₓ. The thermal oxidation gradually converts the layer 22b of Si₍₁₋ₓ₎Geₓ into a layer of SiO₂, starting from the upper surface of the layer 22b toward the interface with the layer 21b of Si. Indeed, the layer 22b is exposed to an oxidizing environment, generally oxygen at high temperatures. Oxidation is carried out at a temperature ranging between 700° C. and 1,100° C., preferably between 850° C. and 1,050° C., in order to enrich the layer 21b of silicon with germanium. The silicon atoms in the layer 22b oxidize in order to form silicon dioxide SiO₂, while the germanium atoms do not oxidize as easily. The process pushes the germanium atoms toward the unoxidized region and toward the silicon layer 21b, enriching the layer 21b with germanium. This sub-step then allows the germanium atoms to diffuse toward the silicon layer 21b in the second region ZP and the layer 22b to be converted into a layer of SiO₂. For example, a silicon layer 21b enriched with a germanium content ranging between 10% and 80%, preferably between 10% and 50% or even between 20% and 40%, and more preferably between 20% and 30%, is obtained. The second sub-step (e′2) involves thermally annealing the structure in order to homogenize the silicon layer 21b previously enriched with germanium in the second region ZP. The thermal annealing is carried out at a temperature ranging between 700° C. and 1,100° C., preferably between 850° C. and 1,050° C., for a period ranging between 30 minutes and 3 hours. To ensure sufficient and homogeneous diffusion of the germanium, the annealing time must be adapted to the temperature that is used in order to obtain a sufficient thermal budget: by way of an example, the sub-step (e′2) is carried out at 900° C. for 3 hours, or at 1,050° C. for 30 minutes. This allows a strained crystal lattice to be obtained in the silicon layer 21b enriched with germanium that is completely homogeneous. The crystal lattices experience a compression strain, which increases the mobility of the holes. The temperature range selected for thermal annealing also at the same time allows the structure of the isolation trench (STI) to become more dense and solid. The third sub-step (e′3) involves removing the oxidized layer 2b formed in the second region ZP by etching. The intermediate structure obtained on completion of the fifth step (e′) is illustrated in FIG. 7e.

The sixth step (f) involves manufacturing an isolation trench (STI) extending from the epitaxial layer 22 to the bulk semiconductor substrate 20. The second step (f) comprises the following sub-steps: the first sub-step (f′1) involves depositing a protective structure over the entire surface of the layer 22 of Si₍₁₋ₓ₎Geₓ, comprising a first protective layer of SiO₂ and a second protective layer of silicon nitride Si₃N₄. The second sub-step (f2) involves manufacturing a bulk semiconductor substrate 20 using lithography and etching operations. The third sub-step (f′3) involves filling the trench with an insulating material, typically silicon oxide SiO₂. This is achieved by chemical vapor deposition (CVD). The insulating material is filled by depositing TEOS (Si(OC₂H₅)₄) used as a precursor in chemical vapor deposition methods in order to form the silicon oxide filling. The TEOS is deposited at a low temperature below 650° C., for example at 540° C. The fourth sub-step (f′4) involves planarizing the upper surface of the wafer by mechanical-chemical polishing with a barrier on the layer of Si₃N₄. The intermediate structure obtained on completion of the sixth step (f) is illustrated in FIG. 7f. Optionally, after depositing the isolation trench (STI), annealing at 1,050° C. is carried out in order to densify the isolation trench (STI).

The seventh step (g′) involves manufacturing the NMOS transistor in the strained layer 21a and manufacturing the PMOS transistor in the strained layer 21b. Both transistors are manufactured using standard CMOS manufacturing steps, including lithography, doping in order to form the drains D and the sources S, and deposition of the gates G. The intermediate structure obtained on completion of the seventh step (g′) is illustrated in FIG. 7g.

1. A method (P1, P2) for manufacturing a semiconductor device (D1) comprising at least one PMOS transistor and at least one NMOS transistor, said method comprising the following steps of:
(a) depositing a layer of Si₍₁₋ₓ₎Geₓ alloy onto a semiconductor-on-insulator (SOI) substrate (SUB), said substrate (SUB) comprising a silicon layer disposed on a buried oxide layer (BOX) that is disposed on a bulk support made of a semiconductor material;
(b) manufacturing an isolation trench (STI) extending from the layer of Si₍₁₋ₓ₎Geₓ to at least the buried oxide layer (BOX), the dielectric isolation trench (STI) separating a first region (ZN) dedicated to said NMOS transistor and a second region (ZP) dedicated to said PMOS transistor;
(c) masking the portion of the layer of Si₍₁₋ₓ₎Geₓ located in the second region (ZP) by depositing a first masking structure;
(d) inducing a strain in the crystal lattice of the silicon layer located in the first region (ZN) using a top recrystallization method on the previously amorphized layer of Si₍₁₋ₓ₎Geₓ (STRASS);
(e) masking the portion of the silicon layer located in the first region (ZN) by depositing a second masking structure and etching the first masking structure;
(f) inducing a strain in the crystal lattice of the silicon layer located in the second region (ZP) using a germanium enrichment method.

2. The method (P1, P2) for manufacturing a semiconductor device (D1) as claimed in claim 1, further comprising the following step of: (g) manufacturing the drain and the source (D, S) of the NMOS transistor in the silicon layer located in the first region (ZN), and manufacturing the drain and the source (D2, S2) of the PMOS transistor in the portion of the germanium-enriched silicon layer located in the second region (ZP).

3. The method (P1, P2) for manufacturing a semiconductor device (D1) as claimed in claim 1, further comprising a step of thinning by etching the portion of the layer of Si₍₁₋ₓ₎Geₓ located in the second region (ZP) before step f).

4. The method (P1, P2) for manufacturing a semiconductor device (D1) as claimed in claim 1, wherein step (d) comprises the following sub-steps of:
(d1) ion implantation into the stack formed by the semiconductive layer and the layer of Si₍₁₋ₓ₎Geₓ in the first region (ZN) so as to render the silicon layer amorphous and render the layer of Si₍₁₋ₓ₎Geₓ in the first region (ZN) partially amorphous;
(d2) thermal annealing of the structure so as to recrystallize the semiconductive layer and the layer of Si₍₁₋ₓ₎Geₓ in the first region (ZN);
(d3) removing the recrystallized layer of Si₍₁₋ₓ₎Geₓ in the first region (ZN) by etching.

5. The method (P1, P2) for manufacturing a semiconductor device (D1) as claimed in claim 4, wherein the thermal annealing step (d2) is carried out at a temperature below 850° C.

6. The method (P1, P2) for manufacturing a semiconductor device (D1) as claimed in claim 4, wherein the ion implantation step (d1) is carried out with ions comprising silicon or germanium or argon or fluorine, or carbon, or nitrogen or oxygen.

7. The method (P1, P2) for manufacturing a semiconductor device (D1) as claimed in claim 1, wherein step (f) comprises the following sub-steps of:
(f1) thermal oxidation of the layer of Si₍₁₋ₓ₎Geₓ located in the second region (ZP) so as to diffuse any germanium atoms toward the silicon layer in the second region (ZP) and convert the layer of Si₍₁₋ₓ₎Geₓ into a layer of SiO₂;
(f2) thermal annealing of the structure so as to recrystallize the germanium-enriched silicon layer in the second region (ZP);
(f3) removing the layer of SiO₂ formed in the second region (ZP) by etching.

8. The method (P1, P2) for manufacturing a semiconductor device (D1) as claimed in claim 7, wherein the thermal oxidation step (f1) is carried out at a temperature ranging between 700° C. and 1,100° C.

9. The method (P1, P2) for manufacturing a semiconductor device (D1) as claimed in claim 7, wherein the thermal annealing step (f2) is carried out at a temperature ranging between 700° C. and 1,100° C.

10. The method (P1, P2) for manufacturing a semiconductor device (D1) as claimed in claim 1, wherein the deposition carried out during step (a) involves epitaxial growth of a crystalline layer of an alloy of Si₍₁₋ₓ₎Geₓ.

11. The method (P1, P2) for manufacturing a semiconductor device (D1) as claimed in claim 1, wherein the layer of Si₍₁₋ₓ₎Geₓ deposited during step (a) is an amorphous layer, the manufacturing method (P1, P2) further comprising a step of crystallizing said amorphous layer of Si₍₁₋ₓ₎Geₓ implemented before step (d).

12. The method (P1, P2) for manufacturing a semiconductor device (D1) as claimed in claim 1, wherein the layer of Si₍₁₋ₓ₎Geₓ is formed during step (a) with a thickness ranging between 6 nm and 25 nm.

13. The method (P1, P2) for manufacturing a semiconductor device (D1) as claimed in claim 1, wherein the layer (12) of Si₍₁₋ₓ₎Geₓ is formed during step (a) and comprises 20% to 30% germanium.

14. The method (P1, P2) for manufacturing a semiconductor device (D1) as claimed in claim 1, wherein the thickness of the layer of Si₍₁₋ₓ₎Geₓ deposited during step (a) is equal to 8 nm.

15. The method (P1, P2) for manufacturing a semiconductor device (D1) as claimed in claim 1, wherein at least one from among the first masking structure or the second masking structure comprises a layer of SiN disposed on a layer of SiO₂.

16. The method (P1, P2) for manufacturing a semiconductor device (D1) as claimed in claim 1, wherein the step (b) of manufacturing an isolation trench is carried out after the step (a) of depositing a layer of Si₍₁₋ₓ₎Geₓ alloy onto a substrate (SUB) and before the step (c) of masking the portion of the layer of Si₍₁₋ₓ₎Geₓ located in the second region (ZP).

17. The method (P1, P2) for manufacturing a semiconductor device (D1) as claimed in claim 1, wherein the step (b) of manufacturing an isolation trench is carried out after the step (g) of inducing a strain in the crystal lattice of the silicon layer.

18. A semiconductor device (D1) comprising a PMOS transistor and an NMOS transistor separated from each other by a dielectric isolation trench (STI), the NMOS transistor being produced in a crystalline silicon layer disposed on a buried oxide layer (BOX), the lattices of the crystalline silicon layer experiencing internal mechanical tensile strains, the PMOS transistor being produced in a crystalline layer of Si₍₁₋ₓ₎Geₓ disposed on a buried oxide layer (BOX), the lattices of the crystalline layer of Si₍₁₋ₓ₎Geₓ experiencing internal mechanical compression strains.

19. The semiconductor device (D1) as claimed in claim 18, wherein the amplitude of the mechanical tensile strains is greater than or equal to 1 GPa.
